(19) United States
(12) Patent Application Publication
(10) Pub. No.: US 2008/0115728 A1
(43) Pub. Date: May 22, 2008

(54) Plasma Processing Apparatus

(75) Inventors: Ryuichi Matsuda, Hyogo (JP); Masahiko Inoue, Hyogo (JP)

Correspondence Address: BIRCH STEWART KOLASCH & BIRCH, PO BOX 747, FALLS CHURCH, VA, 22040-0747, US

(73) Assignee: Mitsubishi Heavy Industries, Ltd, Tokyo (JP)

(21) Appl. No.: 11/660,862

(22) PCT Filed: Feb. 22, 2006
(86) PCT No.: PCT/JP06/03152

§ 371 Date: Jul. 30, 2007

(30) Foreign Application Priority Data
Feb. 28, 2005 (JP) 2005-053180

(51) Int. Cl. C23C 16/22

(52) U.S. Cl. 118/723 R

(57) ABSTRACT

When the size of a substrate 1 is instructed, a map of uniform sputter-etching possible region based on the relationship between the diameter-size Dp of a high-density plasma region and the height H from the center of the high-density plasma region to the bottom of a plasma diffusion region is read out; on the basis of the internal pressure and the frequency of electromagnetic waves from an antenna 116, the value of the height Hp from the center of the high-density plasma region to the upper surface inside a vacuum chamber 111, and the value of the Dp are obtained; on the basis of the internal pressure and the magnitude of the self-bias potential of the substrate 1, the height Hs between the bottom of the plasma diffusion region and the top surface of a supporting table 113 is obtained; on the basis of the above-mentioned values of Dp, Hp and Hs, the value of the H in the uniform sputter-etching possible region is obtained from the map; and a lifting-and-lowering device 121 is controlled so that H can have the above-mentioned value.

### TECHNICAL FIELD

The present invention relates to a plasma processing apparatus which performs a processing on a surface of a substrate by generating a plasma.

### BACKGROUND ART

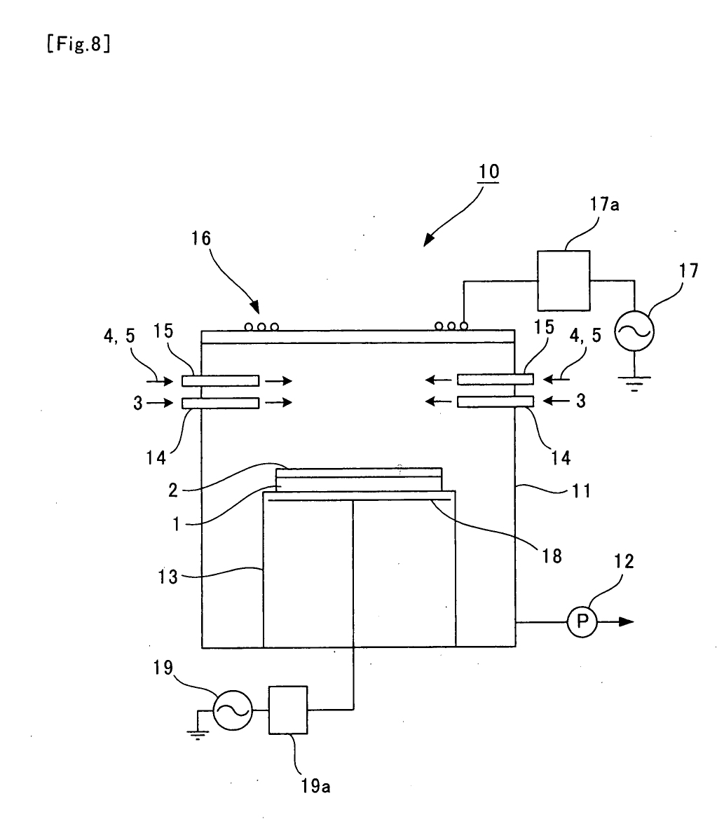

FIG. 8 shows an example of a conventional plasma processing apparatus which performs a processing on a surface of a substrate by generating a plasma.

As FIG. 8 shows, on a floor inside a cylindrical vacuum chamber 11 to which an exhaust pump 12 is connected, a columnar supporting table 13 for supporting a substrate 1 is disposed coaxially with the vacuum chamber 11. Inside the vacuum chamber 11 and over the supporting table 13, a plurality of main supply nozzles 14, which feed a main source gas 3 such as silane (SiH₄) with their tip ends directed towards the axial center of the vacuum chamber 11, are installed, with regular intervals, along the circumferential direction of the vacuum chamber 11. At a position over these main supply nozzles 14, a plurality of auxiliary supply nozzles 15, which feed a sub-source gas 4 such as oxygen (O₂), or a rare gas 5 such as argon, with their tip ends directed towards the axial center of the vacuum chamber 11, are installed, with regular intervals, along the circumferential direction of the vacuum chamber 11.

On a roof of the vacuum chamber 11, a plurality of high-frequency antennas 16, of a shape curled into spiral rings, are disposed coaxially with the vacuum chamber 11. To the high-frequency antennas 16, via a matching apparatus 17a, a high-frequency power source 17 is connected. Inside the supporting table 13, a disc-shaped bias electrode plate 18 is disposed. To the bias electrode plate 18, via a matching apparatus 19a, a high-frequency bias power source (LF power source) 19 is connected.

There is a case in which, for example, aluminum wiring, formed on a semi-conductor wafer, is enveloped by an insulating coating (SiO₂), using such a conventional plasma processing apparatus 10 as mentioned above. In such a case, with the substrate (semi-conductor wafer) 1 being placed on the supporting table 13, the exhaust pump 12 is activated to reduce the pressure inside the vacuum chamber 11 down to a predetermined value, and the high-frequency power source 17 and the high-frequency bias power source 19 are activated, while the gases 3 to 5 are supplied through the supply nozzles 14 and 15. Accordingly, the electromagnetic waves from the high-frequency antenna 16 transforms the gases 3 to 5 into plasma, while the gases 3 to 5 are pulled onto the substrate 1 on the supporting table 13 by a self-bias electric potential produced in the substrate 1. Then, a reaction product (SiO₂) between the main source gas 3 (SiH₄) and the sub-source gas 4 (O₂), is deposited on the substrate 1 to form a coating 2. On the other hand, the coating 2 deposited as protruding from the substrate 1 between the aluminum wiring is sputter-etched by the rare gas 5, which has been transformed into plasma, and thus the coating 2 is formed without producing any void in the substrate 1 between the aluminum wiring.

### Patent Document 1: JPB No. 3258839

### DISCLOSURE OF THE INVENTION

### Problems to be Solved by the Invention

Incidentally, it is extremely important to form the coating 2 with a uniform thickness in the direction along the surface of the substrate 1. For this purpose, it is necessary to achieve both a deposition of the reaction product (SiO₂) in a uniform amount, and a sputter-etching on the reaction product (SiO₂) in a uniform amount, both in the direction along the surface of the substrate 1. However, with the aforementioned conventional plasma processing apparatus 10, it is extremely difficult to sputter-etch the reaction product in a uniform amount, and it becomes even more difficult as the diameter-size of the substrate 1 becomes larger.

Accordingly, an object of the present invention is to provide a plasma processing apparatus capable of easily forming a coating with a uniform thickness in the direction along the surface of the substrate.

### Means for Solving the Problems

A plasma processing apparatus according to a first invention for solving the aforementioned problems is a plasma processing apparatus which includes: a cylindrical vacuum chamber; exhaust means connected to the vacuum chamber; a supporting table disposed in the vacuum chamber and supporting a substrate; a main supply nozzle disposed over the supporting table inside the vacuum chamber, and feeding a main source gas with the tip end thereof directed to an axial center portion of the vacuum chamber; an auxiliary supply nozzle disposed over the supporting table inside the vacuum chamber, and feeding sub-source gas and rare gas with the tip end thereof directed to the axial center portion of the vacuum chamber; a ring-shaped high-frequency antenna disposed in an upper portion of the vacuum chamber, coaxially with the vacuum chamber; power feeding means for antenna connected to the high-frequency antenna, and causing electromagnetic waves to be outputted from the high-frequency antenna; a bias electrode plate disposed inside the supporting table; and high-frequency bias power feeding means connected to the bias electrode plate, and causing a self-bias potential to occur in the substrate. The plasma processing apparatus is characterized by including lifting-and-lowering means which lifts up and down the supporting table and controlling means. The controlling means, when a size of the substrate to be placed on the supporting table is instructed, reads out a uniform sputter-etching map, recorded as being associated with the above-mentioned size of substrate, and showing a uniform sputter-etching possible region based on the relationship between the size Dp of a center diameter, which is between the outer diameter and the inner diameter, of a ring-shaped high-density plasma region formed along the high-frequency antenna, and the height H from the center of the high-density plasma region to the bottom of the plasma diffusion region inside the vacuum chamber. The controlling means, concurrently, obtains, on the basis of the internal pressure of the vacuum chamber and the frequency of electromagnetic waves to be produced from the high-frequency antenna, the height Hp between the center of the high-density plasma region and the upper surface inside the vacuum chamber, and also obtains a value of the Dp. Meanwhile, the controlling means obtains, on the basis of the internal pressure of the vacuum chamber and the magnitude of the self-bias potential to be produced in the substrate, the height Hs between the bottom portion of the plasma diffusion region and the top surface of the supporting table. After that, the controlling means obtains, on the basis of the above-mentioned value of Dp, the above-mentioned value of Hp and the above-mentioned value of Hs, a value of the H in a uniform sputter-etching possible region from the read-out map. Then, the controlling means controls the lifting-and-lowering means and lifts up and down the supporting table so that H can have the above-mentioned value.

A plasma processing apparatus according to a second invention is the plasma processing apparatus of the first invention, and is characterized by further including main-supply-nozzle adjusting means which adjusts the main supply nozzle so as to change the distance between the tip end of the main supply nozzle and the axial center of the vacuum chamber. The plasma processing apparatus is characterized in that, when a size of the substrate to be placed on the supporting table is instructed, the controlling means further reads out a uniform deposition map, recorded as being associated with the above-mentioned size of substrate, and showing a uniform deposition possible region based on the relationship between the distance Dn from the tip end of the main supply nozzle to the axial center of the vacuum chamber and the height Hn from the axial center of the main nozzle to the top surface of the supporting table. The controlling means then obtains values of the H, and the Hn, on the basis of the values of the Dp, the Hp and the Hs, from the region where the uniform deposition possible region of the read-out uniform deposition map overlaps the uniform sputter-etching possible region of the uniform sputter-etching map, and also obtains a value of the Dn. Then the controlling means controls the main-supply-nozzle adjusting means and adjusts the main supply nozzle so that Dn can have the above-mentioned value.

A plasma processing apparatus according to a third invention is a plasma processing apparatus which includes: a cylindrical vacuum chamber; exhaust means connected to the vacuum chamber; a supporting table disposed in the vacuum chamber and supporting a substrate; a main supply nozzle disposed over the supporting table inside the vacuum chamber, and feeding a main source gas with the tip end thereof directed to the axial center portion of the vacuum chamber; an auxiliary supply nozzle disposed over the supporting table inside the vacuum chamber, and feeding sub-source gas and rare gas with the tip end thereof directed to the axial center portion of the vacuum chamber; a ring-shaped high-frequency antenna disposed in an upper portion of the vacuum chamber, coaxially with the vacuum chamber; power feeding means for antenna connected to the high-frequency antenna, and causing electromagnetic waves to be outputted from the high-frequency antenna; a bias electrode plate disposed inside the supporting table; and high-frequency bias power feeding means connected to the bias electrode plate, and causing the self-bias potential to occur in the substrate. The plasma processing apparatus characterized in that the high-frequency antenna is composed of a plurality of high-frequency antennas with different diameter-sizes, and the power feeding means for antenna is capable of feeding power only to selected one of the high-frequency antennas. The plasma processing apparatus is characterized by including controlling means. The controlling means, when a size of the substrate to be placed on the supporting table is instructed, reads out a uniform sputter-etching map, recorded as being associated with the above-mentioned size of substrate, and showing a uniform sputter-etching possible region based on the relationship between the size Dp of a center diameter, which is between the outer diameter and the inner diameter, of a ring-shaped high-density plasma region formed along the high-frequency antenna, and the height H from the center of the high-density plasma region to the bottom of the plasma diffusion region inside the vacuum chamber. The controlling means, concurrently, obtains the height Hp between the center of the high-density plasma region and the upper surface inside the vacuum chamber, on the basis of the internal pressure of the vacuum chamber and frequency of electromagnetic waves to be produced from the high-frequency antenna. The controlling means also obtains a value of the H by obtaining the height Hs between the bottom portion of the plasma diffusion region and the top surface of the supporting table, on the basis of the internal pressure of the vacuum chamber and the magnitude of the self-bias potential to be produced in the substrate. The controlling means then obtains a value of the Dp in a uniform sputter-etching possible region from the read-out map, on the basis of the above-mentioned value of H. After that, the controlling means obtains a diameter-size Da of the high-frequency antenna to be used, from the above-mentioned value of Dp, on the basis of the internal pressure of the vacuum chamber and frequency of electromagnetic waves to be produced from the high-frequency antenna. Then, the controlling means selects the high-frequency antenna to be used, on the basis of the above-mentioned value of Da, and controls the power feeding means for antenna so that the power can be fed only to the selected one of high-frequency antenna.

A plasma processing apparatus according to a fourth invention is the plasma processing apparatus of the third invention, and is characterized by further including main-supply-nozzle adjusting means which adjusts the main supply nozzle so as to change the distance between the tip end of the main supply nozzle and the axial center of the vacuum chamber. The plasma processing apparatus is characterized in that the controlling means, when a size of the substrate to be placed on the supporting table is instructed, further reads out a uniform deposition map, recorded as being associated with the above-mentioned size of substrate, and showing a uniform deposition possible region based on the relationship between the distance Dn from the tip end of the main supply nozzle to the axial center of the vacuum chamber and the height Hn from the axial center of the main nozzle to the top surface of the supporting table. The controlling means then obtains values of the Dp and the Dn, on the basis of the values of the H, and the Hn, from the region where the uniform deposition possible region of the read-out uniform deposition map overlaps the uniform sputter-etching possible region of the uniform sputter-etching map. The controlling means controls the main-supply-nozzle adjusting means and adjusts the main supply nozzle so that Dn can have the above-mentioned value.

### EFFECTS OF THE INVENTION

According to the plasma processing apparatus of the present invention, in the direction along the surface of the substrate, while the reaction product being deposited in a uniform amount, the reaction product can easily be sputter-etched in a uniform amount. As a result, it can easily be carried out to form a coating in a uniform thickness in the direction along the surface of the substrate, and, in particular, as the diameter-size of the substrate becomes larger, the easiness can be expressed more prominently.

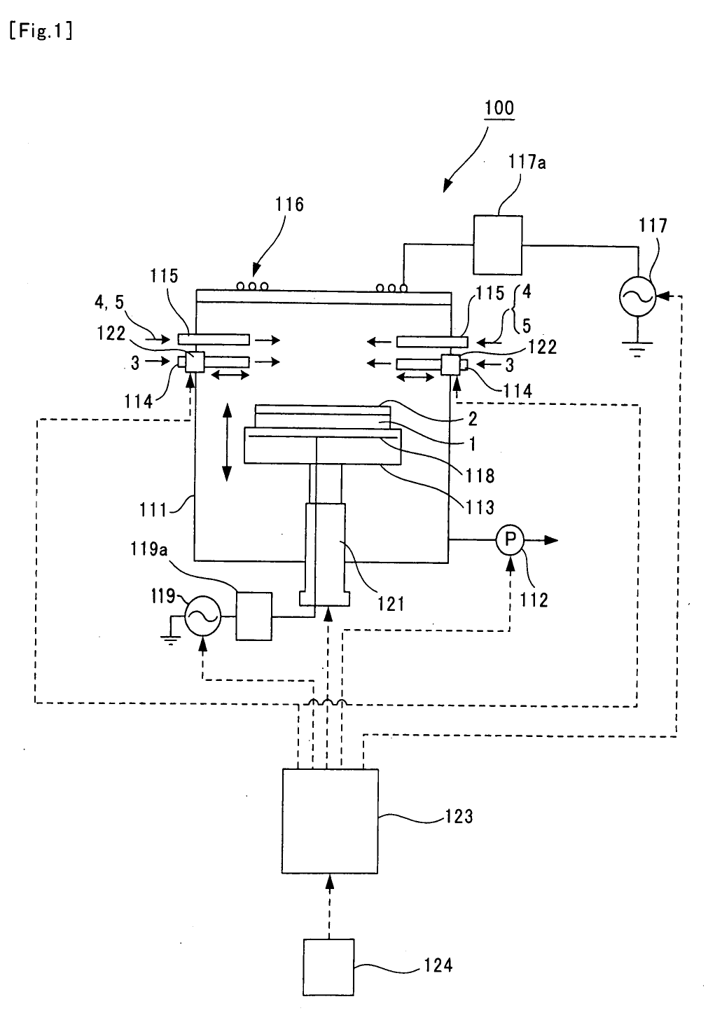

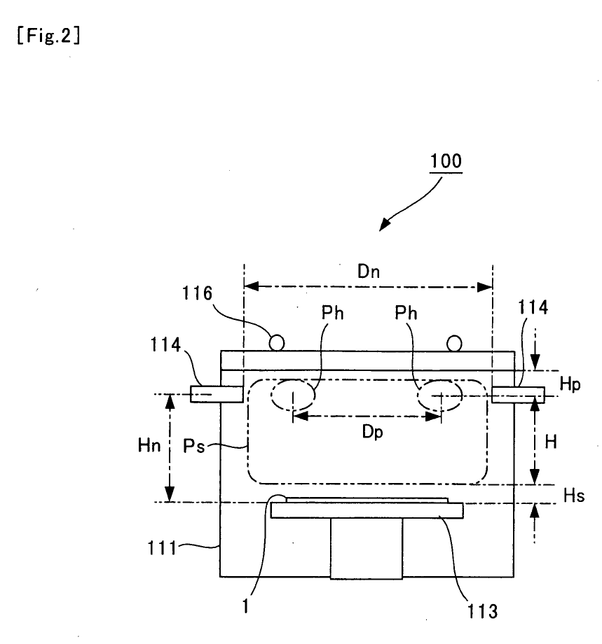

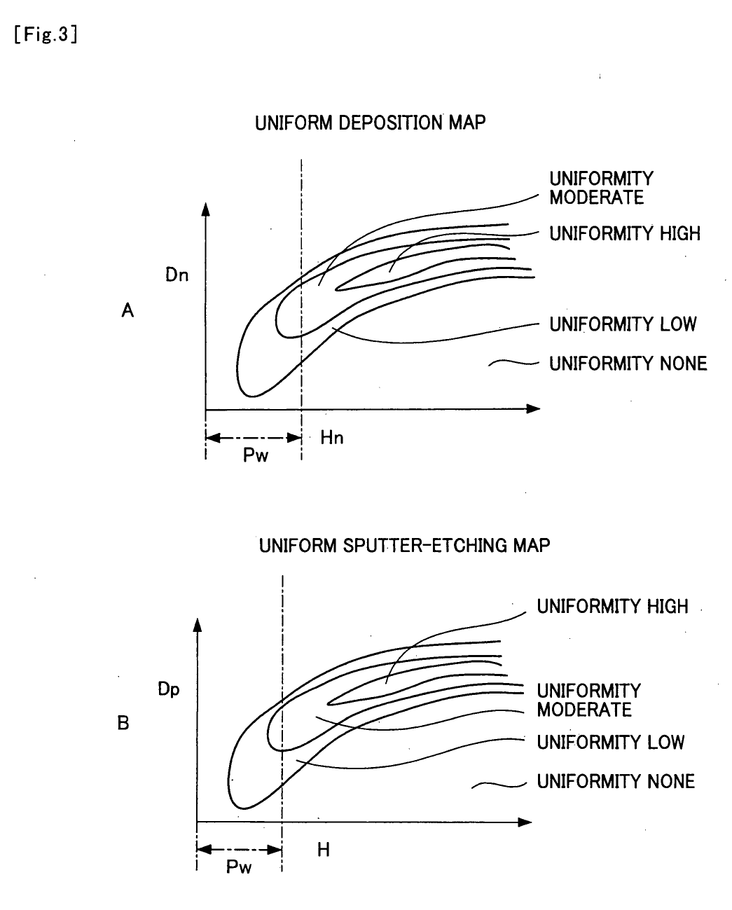

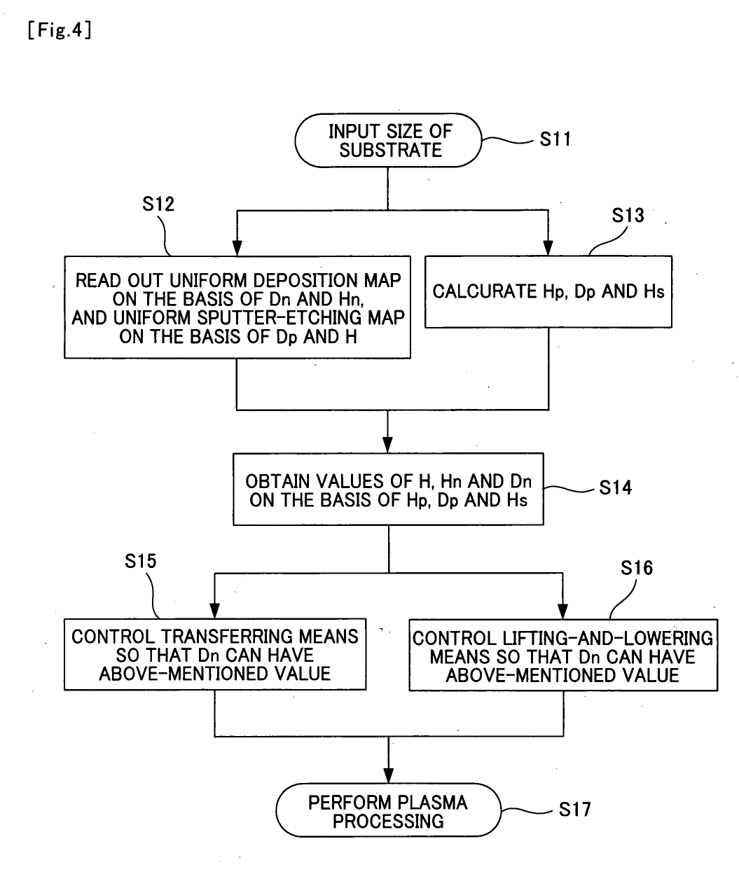

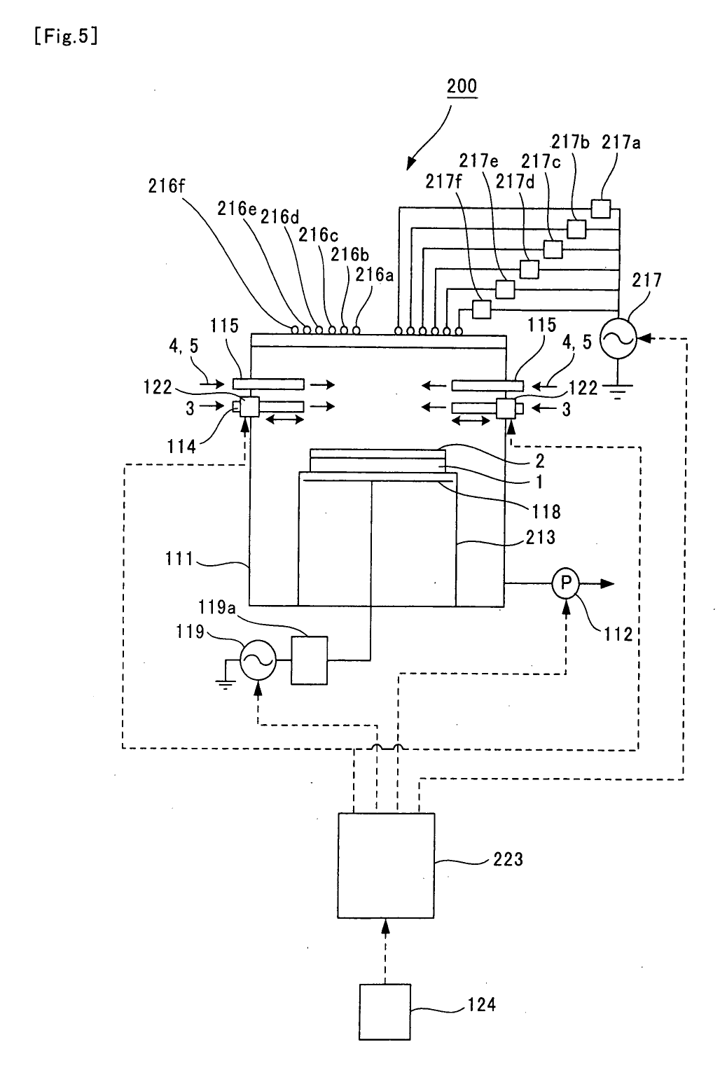

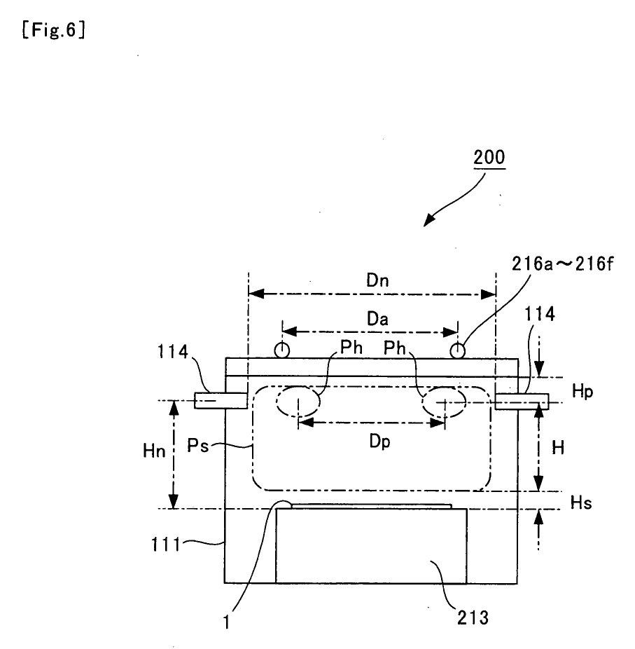

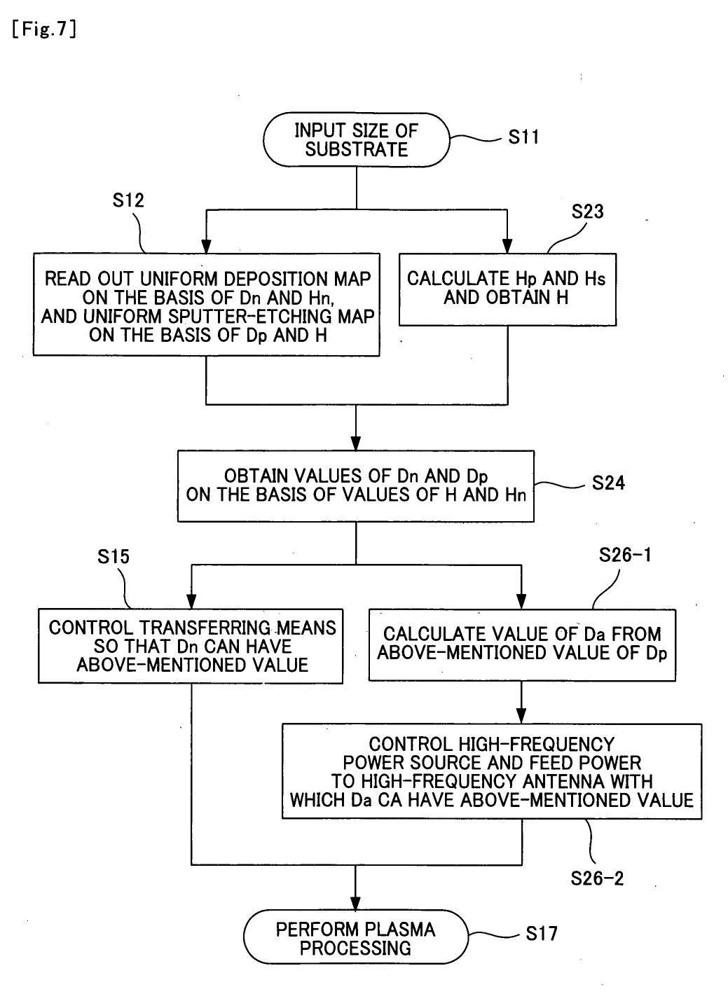

### BRIEF DESCRIPTION OF THE DRAWINGS

[FIG. 1] A schematic configuration view of a plasma processing apparatus according to a first embodiment of the present invention.

[FIG. 2] An explanatory view of a main part of the plasma processing apparatus of FIG. 1.

[FIG. 3] 3A is a uniform deposition map recorded in a controlling device of the plasma processing apparatus of FIG. 1, and 3B is a sputter-etching map recorded in the controlling device of the plasma processing apparatus of FIG. 1.

[FIG. 4] A flow chart showing a procedure of a plasma processing method.

[FIG. 5] A schematic configuration view of a plasma processing apparatus according to a second embodiment of the present invention.

[FIG. 6] An explanatory view of a main part of the plasma processing apparatus of FIG. 5.

[FIG. 7] A flow chart showing a procedure of a plasma processing method.

[FIG. 8] A schematic configuration view of a conventional plasma processing apparatus.

### BEST MODE FOR CARRYING OUT THE INVENTION

Embodiments of a plasma processing apparatus of the present invention will be described below by referring to the drawings, but the present invention is not limited to the embodiments below.

### First Embodiment

A first embodiment of a plasma processing apparatus of the present invention will be described by referring to FIGS. 1 to 4. FIG. 1 is a schematic configuration view of the plasma processing apparatus. FIG. 2 is an explanatory view of a main part of the plasma processing apparatus of FIG. 1. FIG. 3A is a uniform deposition map recorded in a controlling device of the plasma processing apparatus of FIG. 1, and 3B is a sputter-etching map recorded in the controlling device of the plasma processing apparatus of FIG. 1. FIG. 4 is a flow chart showing a procedure of a plasma processing method.

FIG. 1 shows that, a lifting-and-lowering apparatus 121, as lifting-and-lowering means, is provided at a lower portion inside a cylindrical vacuum chamber 111, to which an exhaust pump 112, as exhaust means, is connected. A disc-shaped supporting table 113 which supports a substrate 1 is mounted, coaxially with the vacuum chamber 111, to the lifting-and-lowering apparatus 121.

Inside the vacuum chamber 111 and over the supporting table 113, a plurality of main supply nozzles 14, which feed a main source gas 3 such as silane (SiH₄) with their tip ends directed towards the axial center of the vessel chamber 111, are installed, with regular intervals, along the circumferential direction of the vacuum chamber 111. A transferring device 122, as main-supply-nozzle adjusting means, is provided to each of these main supply nozzles 114. The transferring device 122 adjusts the main supply nozzle 114 by moving the main supply nozzle 114 with respect to the vacuum chamber 111 so as to change the distance between the tip end of the main supply nozzle 114 and the axial center of the vacuum chamber 111.

At a position over these main supply nozzles 114, a plurality of auxiliary supply nozzles 115, which feed a sub-source gas 4 such as oxygen (O₂), or a rare gas 5 such as argon, with their tip ends directed towards the axial center of the vessel chamber 111, are installed, with regular intervals, along the circumferential direction of the vacuum chamber 111.

On a roof of the vacuum chamber 11, a plurality of high-frequency antennas 16, of a shape curled into spiral rings, are disposed coaxially with the vacuum chamber 11. To the high-frequency antenna 116, via a matching apparatus 117a, a high-frequency power source 117 is connected. Inside the supporting table 113, a disc-shaped bias electrode plate 118 is disposed. To the bias electrode plate 118, via a matching apparatus 119a, a high-frequency bias power source (LF power source) 119 is connected.

The exhaust pump 112, the high-frequency power source 117, the high-frequency bias power source 119, the lifting-and-lowering apparatus 121, and the transferring device 122 are electrically connected to an output unit of a controlling device 123. To an input unit of the controlling device 123, an input device 124 with which information is inputted, is electrically connected. The controlling device 123 is designed to control, according to the information and the like inputted with the input device 124, the exhaust pump 112, the high-frequency power source 117, the high-frequency bias power source 119, the lifting-and-lowering apparatus 121, and the transferring device 122 (detailed description will be given later).

It should be noted that, in this embodiment, the high-frequency power source 117, the matching apparatus 117a and the like compose power feeding means for antenna, while the high-frequency bias power source 119, the matching apparatus 119a and the like compose high-frequency bias power feeding means. The controlling device 123, the input device 124 and the like compose controlling means.

Subsequently, a description will be given regarding a plasma processing method in a case where, using a plasma processing apparatus 100 of this embodiment such as described above, aluminum wiring formed on a semi-conductor wafer is enveloped with an insulating coating (SiO₂).

As shown in FIG. 4, with the substrate (semi-conductor wafer) 1 being positioned and fixed on the supporting table 113, the size of the substrate 1 (diameter Dw and thickness Hw) are inputted, with the input device 124, into the controlling device 123 (S11). Then, the controlling device 123 reads out a uniform deposition map (see FIG. 3A) which is recorded as being associated with the size of the substrate 1, and which illustrates an area where uniform deposition is possible, the possibility depending upon the relationship between the distance Dn (see FIG. 2) from the tip end of the main supply nozzle 114 to the axial center of the vacuum chamber 111, and the height Hn (see FIG. 2) from the axial center of the main supply nozzle 114 to the top surface of the supporting table 113. The controlling device 123 also reads out a uniform sputter-etching map (see FIG. 3B) which is recorded as being associated with the size of the substrate 1, and which illustrates an area where uniform sputter-etching is possible, the possibility depending upon the relationship between the size Dp (see FIG. 2) of the center diameter, between the outer diameter and the inner diameter, of a ring-shaped high-density plasma region Ph formed along the high-frequency antenna 116, and the height H (see FIG. 2) from the center of the high-density plasma region Ph to the bottom of the plasma diffusion region Ps (S12).

Concurrently, the controlling device 123, on the basis of the internal pressure of the vacuum chamber 111 and the frequency of the electromagnetic waves to be produced from the high-frequency antenna 116, both of which are set as being associated with the size of the substrate 1, obtains the height Hp (see FIG. 2) between the center of the high-density plasma region Ph and the upper surface inside the vacuum chamber 111 (Hp has an inversely proportional relationship with the magnitude of the internal pressure, and an inversely proportional relationship with the frequency), and also obtains the value of Dp (the Dp has an inversely proportional relationship with the magnitude of the internal pressure, and a proportional relationship with the frequency, that is a proportional relationship with the magnitude of the electric current flowing through the high-frequency antenna 116, which depends on the impedance of the high-frequency antenna 116). On the other hand, on the basis of the internal pressure of the vacuum chamber 111 and the magnitude of the self-bias potential to be produced in the substrate 1, both of which are set as being associated with the size of the substrate 1, obtains the height (sheath thickness) Hs (see FIG. 2) between the bottom of the plasma diffusion region Ps and the top surface of the supporting table 113 (the Hs has an inversely proportional relationship with the magnitude of the internal pressure, and a proportional relationship with the self-bias potential) (S13).

On the basis of the values of the Dp, the Hp and the Hs, obtained as described above, the controlling device 123 excludes, from the area where the uniform deposition possible region overlaps the uniform sputter-etching possible region, a region Pw where damage, due to the high-density plasma region Ph, occurs in the substrate 1. Thus the controlling device 123 obtains values of the H and the Hn, which values can create the highest uniformity, and obtains the value of the Dn (S14).

Subsequently, the controlling device 123 controls the transferring devices 122, and moves the main supply nozzles 114 so that the above-mentioned value Dn can be set (S15). The controlling device 123 also controls the lifting-and-lowering device 121, and lifts up and down the supporting table 113 so that the above-mentioned value H can be set (S16).

Once the setting-up is done as described above, the controlling device 123 activates the exhaust pump 112, and reduces the pressure inside the vacuum chamber to a predetermined value. The controlling device also activates the high-frequency power source 117 and the high-frequency bias power source 119, and supplies the gases 3 to 5 through the supply nozzles 114 and 115. Thus, the gases 3 to 5 are transformed into plasma by the electromagnetic waves from the high-frequency antenna 116, and are pulled onto the substrate 1 on the supporting table 113 by a self-bias electric potential produced in the substrate 1. Then, a reaction product (SiO₂) between the main source gas 3 (SiH₄) and the sub-source gas 4 (O₂), is deposited on the substrate 1 to form the coating 2. On the other hand, the coating 2 deposited as protruding from the substrate 1 between the aluminum wiring is sputter-etched by the rare gas 5, which has been transformed to be plasma, and thus the coating 2 is formed without producing any void in the substrate 1 between the aluminum wiring. In this way, a plasma processing is performed on the substrate 1 (S17).

At this time, in the plasma processing apparatus 100 of this embodiment, as described above, the positions of the tip ends of the main supply nozzles 14 and the height position of the supporting table 13 are set up, as being associated with the size of the substrate 1, to make the uniform deposition possible region overlap the uniform sputter-etching possible region. Accordingly, the reaction product (SiO₂) is deposited in a uniform amount in the direction along the surface of the substrate 1, and at the same time, a sputter-etching can be performed on the reaction product (SiO₂) in a uniform amount.

As a result, according to the plasma processing apparatus 100 of this embodiment, it can easily be carried out to form the coating 2 in a uniform thickness in the direction along the surface of the substrate, and, in particular, as the diameter-size of the substrate 1 becomes larger, the easiness can be expressed more prominently.

### SECOND EMBODIMENT

A second embodiment of a plasma processing apparatus of the present invention will be described by referring to FIGS. 5 to 7. FIG. 5 is a schematic configuration view of the plasma processing apparatus. FIG. 6 is an explanatory view of a main part of the plasma processing apparatus of FIG. 5. FIG. 7 is a flow chart showing a procedure of a plasma processing method. It should be noted that similar reference numerals are given to similar parts to those of the above-described first embodiment. Thus, descriptions that overlap those in the above-described first embodiment will be omitted.

As FIG. 5 shows, on a floor inside a vacuum chamber 111, a columnar supporting table 213 for supporting a substrate 1 is disposed coaxially with the vacuum chamber 111. On a roof of the vacuum chamber 111, a plurality of ring-shaped high-frequency antennas 216a to 216f, each with a different diameter size from others, are disposed coaxially with the vacuum chamber 111. The high-frequency antennas 216a to 216f, via a matching apparatus 217a to 217f, are connected to a high-frequency power source 217. The high-frequency power source 217 is electrically connected to an output unit of a controlling device 223, and the controlling device 223 is designed to feed power, from the high-frequency power source 217, only to those selected from the high-frequency antennas 216a to 216f.

To put it another way, in the plasma processing apparatus 100 of the above-described first embodiment, the supporting table 113 is provided on the lifting-and-lowering apparatus 121 to make it possible to be lifted up-and-down while the single high-frequency antenna 116 is used. In contrast, in a plasma processing apparatus 200 of this embodiment, the plurality of ring-shaped high-frequency antennas 216a to 216f with different diameter sizes are provided to make it possible to be fed power selectively, while the supporting table 213 that is placed on and fixed to the vacuum chamber 111 is designed to be used.

It should be noted that, in this embodiment, the high-frequency power source 217, the matching apparatuses 217a to 217f and the like compose power feeding means for antenna, while the controlling device 223, the input device 124 and the like compose controlling means.

Subsequently, description will be given regarding a plasma processing method using the plasma processing apparatus 200 of this embodiment such as described above.

As shown in FIG. 7, with the substrate (semi-conductor wafer) 1 being positioned and fixed on the supporting table 213, the size of the substrate 1 (diameter Dw and thickness Hw) are inputted, with an input device 124, into the controlling device 223 (S11). Then, the controlling device 223, as in the case of the above-described first embodiment, reads out the maps (see FIG. 3A and FIG. 3B) which are recorded as being associated with the size of the substrate 1 (S12).

Concurrently, the controlling device 223, on the basis of the internal pressure of the vacuum chamber 111 and the frequency of the electromagnetic waves to be produced from the high-frequency antennas 216a to 216f, both of which are set as being associated with the size of the substrate 1, obtains, as in the case of the above-described first embodiment, the height Hp (see FIG. 6). The controlling device 223, on the basis of the internal pressure of the vacuum chamber 111 and the magnitude of the self-bias potential to be produced in a bias electrode plate 118, both of which are set as being associated with the size of the substrate 1, also obtains the Hs (see FIG. 6) and thereby obtains the value of the H (see FIG. 6) (S23). Note that the value of the Hn (see FIG. 6) is constant.

On the basis of the values of the H and the Hn, obtained as described above, the controlling device 223 obtains, from the area where the uniform deposition possible region overlaps the uniform sputter-etching possible region, of the maps, values of the Dn and the Dp, which values can create the highest uniformity (S24).

Subsequently, the controlling device 223, as in the case of the above-described first embodiment, controls the transferring device 122 and moves the main supply nozzles 114 so that the above-mentioned value Dn thus obtained can be set (S15).

In addition, the controlling device 223, on the basis of the internal pressure of the vacuum chamber 111 and the frequency of the electromagnetic waves to be produced from the high-frequency antenna 116, both of which are set as being associated with the size of the substrate 1, obtains, from the value of the above-mentioned Dp, the diameter size Da (see FIG. 6) one of the high-frequency antennas 216a to 216f to be used (the Dp has an inversely proportional relationship with the magnitude of the internal pressure; has a proportional relationship with the frequency, that is, has a proportional relationship with the magnitude of the electric current flowing through each of the high-frequency antennas 216a to 216f, which magnitude is defined by the impedance of the high-frequency antennas 216a to 216f; and has a proportional relationship with the value of the above-mentioned Da) (S26-1).

Then, the controlling device 223, according to the value of the above-mentioned Da thus obtained, selects one of the high-frequency antennas 216a to 216f to be used, and controls the high-frequency power source 217 so that only the selected one of the high-frequency antennas 216a to 216f can be fed the power (S26-2).

Once the setting-up is done as described above, the controlling device 223 operates as in the case of the above-described first embodiment, and a plasma processing is performed on the substrate 1 (S17).

To put it another way, in the plasma processing 100 of the above-described first embodiment, the positions of the tip ends of the main supply nozzles 114 and the height position of the supporting table 113 are set up, as being associated with the size of the substrate 1, to make the uniform deposition possible region overlap the uniform sputter-etching possible region. On the other hand, in the plasma processing 200 of this embodiment, the positions of the tip ends of the main supply nozzles 114 and the high-frequency antennas 216a to 216f to be used are set up, as being associated with the size of the substrate 1, to make the uniform deposition possible region overlap the uniform sputter-etching possible region.

Accordingly, in the plasma processing apparatus 200 of this embodiment, as in the case of the above-described first embodiment, the reaction product (SiO₂) is deposited in a uniform amount in the direction along the surface of the substrate 1, and at the same time, a sputter-etching can be performed on the reaction product (SiO₂) in a uniform amount.

As a result, according to the plasma processing apparatus 200 of the present invention, as in the case of the above-described first embodiment, it can easily be carried out to form a coating 2 in a uniform thickness in the direction along the surface of the substrate, and, in particular, as the diameter-size of the substrate 1 becomes larger, the easiness can be expressed more prominently.

### OTHER EMBODIMENTS

It should be noted that, in the first and the second embodiments described above, the main supply nozzles 114 are moved, with respect to the vacuum chamber 111, by the transferring devices 122, and thus the main supply nozzles 114 is adjusted so as to change the distance between the tip ends of the main supply nozzles 114 and the axial center of the vacuum chamber 111. It is also possible, however, that, for example, by omitting the transferring devices 122 and by providing a plurality of main supply nozzles with various lengths, the main supply nozzles can be adjusted by exchanging the main supply nozzles attached to the vacuum chamber so as to change the distance between the tip ends of the main supply nozzles and the axial center of the vacuum chamber.

Furthermore, in a case where it is relatively easy, under the conditions including the diameter-size of a substrate 1, to deposit the reaction product in a uniform amount in the direction along the surface of the substrate 1, it is also possible to provide the main supply nozzles as being fixed with a distance between the tip ends of the main supply nozzles and the axial center of the vacuum chamber being set in advance at a certain value.

### INDUSTRIAL APPLICABILITY

According to the plasma processing apparatus of the present invention, it can easily be carried out to form a coating in a uniform thickness in the direction along the surface of the substrate, and, in particular, as the diameter-size of the substrate becomes larger, the easiness can be expressed more prominently. For this reason, the plasma processing apparatus can be used, industrially, in an enormously beneficial way.

1. A plasma processing apparatus which includes:
a cylindrical vacuum chamber;
exhaust means connected to said vacuum chamber;
a supporting table disposed in the vacuum chamber and supporting a substrate;
a main supply nozzle disposed over said supporting table inside said vacuum chamber, and feeding a main source gas with the tip end thereof directed to an axial center portion of the vacuum chamber;
an auxiliary supply nozzle disposed over said supporting table inside said vacuum chamber, and feeding sub-source gas and rare gas with the tip end thereof directed to the axial center portion of said vacuum chamber;
a ring-shaped high-frequency antenna disposed in an upper portion of said vacuum chamber, coaxially with said vacuum chamber;
power feeding means for antenna connected to said high-frequency antenna, and causing electromagnetic waves to be outputted from said high-frequency antenna;
a bias electrode plate disposed inside said supporting table; and
high-frequency bias power feeding means connected to said bias electrode plate, and causing a self-bias potential to occur in said substrate,
the plasma processing apparatus characterized by comprising:
lifting-and-lowering means which lifts up and down said supporting table; and
controlling means which,
when a size of said substrate to be placed on said supporting table is instructed,
reads out a uniform sputter-etching map, recorded as being associated with the above-mentioned size of substrate, and showing a uniform sputter-etching possible region based on the relationship between: the size Dp of a center diameter, which is between the outer diameter and the inner diameter, of a ring-shaped high-density plasma region formed along said high-frequency antenna; and the height H from said center of said high-density plasma region to the bottom of the plasma diffusion region inside the vacuum chamber;
concurrently, obtains, on the basis of the internal pressure of said vacuum chamber and the frequency of electromagnetic waves to be produced from said high-frequency antenna, the height Hp between said center of said high-density plasma region and the upper surface inside said vacuum chamber, and also obtains a value of said Dp, meanwhile, said controlling means obtains, on the basis of the internal pressure of said vacuum chamber and the magnitude of the self-bias potential to be produced in said substrate, the height Hs between the bottom portion of said plasma diffusion region and the top surface of said supporting table;
after that, obtains on the basis of the above-mentioned value of Dp, the above-mentioned value of Hp and the above-mentioned value of Hs, a value of said H in a uniform sputter-etching possible region from said read-out map;
and then controls said lifting-and-lowering means and lifts up and down said supporting table so that H can have the above-mentioned value.

2. The plasma processing apparatus according to claim 1, characterized by further comprising:
main-supply-nozzle adjusting means which adjusts said main supply nozzle so as to change the distance between the tip end of said main supply nozzle and the axial center of said vacuum chamber, and characterized in that
said controlling means,
when a size of said substrate to be placed on said supporting table is instructed,
further reads out a uniform deposition map, recorded as being associated with the above-mentioned size of substrate, and showing a uniform deposition possible region based on the relationship between the distance Dn from the tip end of said main supply nozzle to the axial center of said vacuum chamber and the height Hn from the axial center of said main nozzle to the top surface of said supporting table,
obtains values of said H, and said Hn, on the basis of the values of said Dp, said Hp and said Hs, from the region where the uniform deposition possible region of said read-out uniform deposition map overlaps the uniform sputter-etching possible region of said uniform sputter-etching map, and obtains also a value of said Dn,
and then controls said main-supply-nozzle adjusting means and adjusts said main supply nozzle so that Dn can have the above-mentioned value.

3. A plasma processing apparatus which includes:
a cylindrical vacuum chamber;
exhaust means connected to said vacuum chamber;
a supporting table disposed in the vacuum chamber and supporting a substrate;
a main supply nozzle disposed over said supporting table inside said vacuum chamber, and feeding a main source gas with the tip end thereof directed to the axial center portion of the vacuum chamber;
an auxiliary supply nozzle disposed over said supporting table inside said vacuum chamber, and feeding sub-source gas and rare gas with the tip end thereof directed to the axial center portion of said vacuum chamber;
a ring-shaped high-frequency antenna disposed in an upper portion of said vacuum chamber, coaxially with said vacuum chamber;
power feeding means for antenna connected to said high-frequency antenna, and causing electromagnetic waves to be outputted from said high-frequency antenna;
a bias electrode plate disposed inside said supporting table; and
high-frequency bias power feeding means connected to said bias electrode plate, and causing a self-bias potential to occur in said substrate,
the plasma processing apparatus characterized in that
said high-frequency antenna is composed of a plurality of high-frequency antennas with different diameter-sizes, and
said power feeding means for antenna is capable of feeding power only to selected one of said high-frequency antennas, and
the plasma processing apparatus characterized by comprising:
controlling means which,
when a size of said substrate to be placed on said supporting table is instructed,
reads out a uniform sputter-etching map, recorded as being associated with the above-mentioned size of substrate, and showing a uniform sputter-etching possible region based on the relationship between: the size Dp of a center diameter, which is between the outer diameter and the inner diameter, of a ring-shaped high-density plasma region formed along said high-frequency antenna; and the height H from said center of said high-density plasma region to the bottom of the plasma diffusion region inside the vacuum chamber;
concurrently, obtains a height Hp between said center of said high-density plasma region and the upper surface inside said vacuum chamber, on the basis of the internal pressure of said vacuum chamber and the frequency of electromagnetic waves to be produced from said high-frequency antenna, and also obtains a value of said H by obtaining the height Hs between the bottom portion of said plasma diffusion region and the top surface of said supporting table, on the basis of the internal pressure of said vacuum chamber and the magnitude of the self-bias potential to be produced in said substrate,
obtains a value of said Dp in a uniform sputter-etching possible region from said read-out map, on the basis of the above-mentioned value of H;
after that, obtains a diameter-size Da of said high-frequency antenna to be used, from the above-mentioned value of Dp, on the basis of the internal pressure of said vacuum chamber and the frequency of electromagnetic waves to be produced from said high-frequency antenna, and
selects said high-frequency antenna to be used, on the basis of the above-mentioned value of Da, and controls said power feeding means for antenna so that the power can be fed only to the selected one of high-frequency antenna.

4. The plasma processing apparatus according to claim 3, characterized by further comprising:
main-supply-nozzle adjusting means which adjusts said main supply nozzle so as to change the distance between the tip end of said main supply nozzle and the axial center of said vacuum chamber, and characterized in that
said controlling means,
when a size of said substrate to be placed on said supporting table is instructed,
further reads out a uniform deposition map, recorded as being associated with the above-mentioned size of substrate, and showing a uniform deposition possible region based on the relationship between the distance Dn from the tip end of said main supply nozzle to the axial center of said vacuum chamber and the height Hn from the axial center of said main nozzle to the top surface of said supporting table,
obtains values of said Dp and said Dn, on the basis of the values of said H and said Hn, from the region where the uniform deposition possible region of said read-out uniform deposition map overlaps the uniform sputter-etching possible region of said uniform sputter-etching map,
and then controls said main-supply-nozzle adjusting means and adjusts said main supply nozzle so that Dn can have the above-mentioned value.
